(19) United States
(12) Patent Application Publication
(10) Pub. No.: US 2003/0166306 A1
(43) Pub. Date: Sep. 4, 2003

(54) Method and device for recognition of a target molecule by means of molecularly imprinted polymers

(76) Inventors: Borje Sellergren, Mainz (DE); Beate Dirion, Mainz (DE)

Correspondence Address: BURNS DOANE SWECKER & MATHIS L L P, POST OFFICE BOX 1404, ALEXANDRIA, VA, 22313-1404, US

(21) Appl. No.: 10/362,770

(22) PCT Filed: Aug. 27, 2001
(86) PCT No.: PCT/SE01/01809

(30) Foreign Application Priority Data
Aug. 30, 2000 (SE) 0003048-6

(51) Int. Cl. H01L 21/00

(52) U.S. Cl. 438/8; 438/85

(57) ABSTRACT

The invention relates to a method for the preparation of different molecularly imprinted polzmers for recognition of a target molecule by providing particles, frits or monoliths having initiator confined to the surface thereof in separate compartments, adding different monomer mixtures that may contain a template molecule to each compartment, polymerising said mixtures and finally removing the template and excess monomer(S) from the compartments. The invention also relates to a device containing different molecularly imprinted polymers for recognition of a target molecule.

### TECHNICAL FIELD OF THE INVENTION

The invention relates to a method for the preparation of different molecularly imprinted polymers for recognition of a target molecule and to a device containing different molecularly imprinted polymers for recognition of a target molecule.

### TECHNICAL BACKGROUND

Molecularly imprinted polymers (MIPs), or so called artificial antibodies, are plastics programmed to recognize target molecules, like pharmaceuticals, toxins or environmental pollutants, in complex biological samples¹⁻³. During the last years, applications of the materials as affinity phases in solid phase extractions,^{4, 5} as recognition elements in sensors,⁶ as stationary phases for preparative purifications⁷ or separations of enantiomers^{8, 9} as catalysts¹⁰ or as adsorbents for medical use¹¹ are being actively pursued. Among these applications, solid phase extraction (SPE) is the area where the materials on a short time scale are expected to find their most widespread use. SPE is used to clean up and enrich analytes (i.e. drugs or metabolites, pesticides, toxins) present in complex biological samples such as blood, urine or environmental waters (FIG. 1).

Current methods for drug analysis are strongly depending on efficient SPE techniques. Due to their high potency, many new drugs are now being administered in very low doses. Therefore, the conventional clean-up methods are not efficient enough. However, MIPs can be used to selectively extract the drug from the sample with a high affinity. In an alternative method biological antibodies can be used for the same purpose. It should be noted that MIPs can be produced much faster and in a more reproducible fashion than biological antibodies which are produced by immunisation of laboratory animals. MIPs can be produced and tested within 1-2 weeks compared to 6-12 months for biological antibodies.

Since the biological monitoring of new drug candidates often constitutes bottlenecks in drug development, the rapid availability of efficient analytical methods is expected to bring significant savings in time in the development of new pharmaceutical products. With a new target analyte in hand it is thus important to provide a selective extraction material for the target in a short time.

### SUMMARY OF THE INVENTION

The molecular imprinting protocol presently in use is based on polymerisation of one or more functional monomers with an excess of a crosslinking monomer in presence of a target template molecule, exhibiting a structure similar to the target molecule that is to be recognised (FIG. 2).

A key in this development is the identification and optimisation of the main factors affecting the materials structure and molecular recognition properties. These factors can be the type and concentration of functional monomer, crosslinking monomer, the polymerisation temperature, pressure or solvent of polymerisation. This can be achieved by scaling down the MIP synthesis allowing rapid screening for the recognition properties of large numbers of materials (mini-MIPs) (FIG. 3)¹². Thus, the present automated procedure allows parallel synthesis of 60 MIPs in small autosampler vials. This is followed by an assessment of the recognition properties in a batch equilibrium binding experiment. A problem with this way of evaluating the materials is that no information about the kinetics of the equilibrium reaction is possible to obtain. For this purpose techniques allowing the materials to be directly assessed in the chromatographic flow through mode would be desirable.

The object of the present invention is to provide a screening technique using monolith MIPs and grafted MIPs in a flowthrough format. The characterising features of the present invention are defined in the appended claims.

In accordance with the invention this object has been achieved by a method

a) providing particles, frits or monoliths having initiator confined to the surface thereof in separate compartments;

b) adding different monomer mixtures that may contain a template molecule to each compartment;

c) polymerising said mixtures;

d) removing the template and excess monomer(s) from the compartments.

In accordance with the invention this object has also been achieved by a device

a) providing particles, frits or monoliths having initiator confined to the surface thereof in separate compartments;

b) adding different monomer mixtures that may contain a template molecule to each compartment;

c) polymerising said mixtures;

d) removing the template and excess monomer(s) from the compartments.

Preferred embodiments of the invention are defined in the dependent claims.

### SHORT DESCRIPTION OF THE DRAWINGS

The invention will now be described in more detail giving some preferred and nonrestrictive examples. The following products and methods are claimed as new and of decisive importance for a successful outcome of MIP development. In the drawings

FIG. 1 is a scheme illustrating the principle of solid phase extraction (SPE).

FIG. 2 is a scheme illustrating the principle of molecular imprinting.

FIG. 3 is a scheme illustrating a system for small scale automated synthesis and screening of MIPs.

FIGS. 4-7 are schemes illustrating the methods of invention.

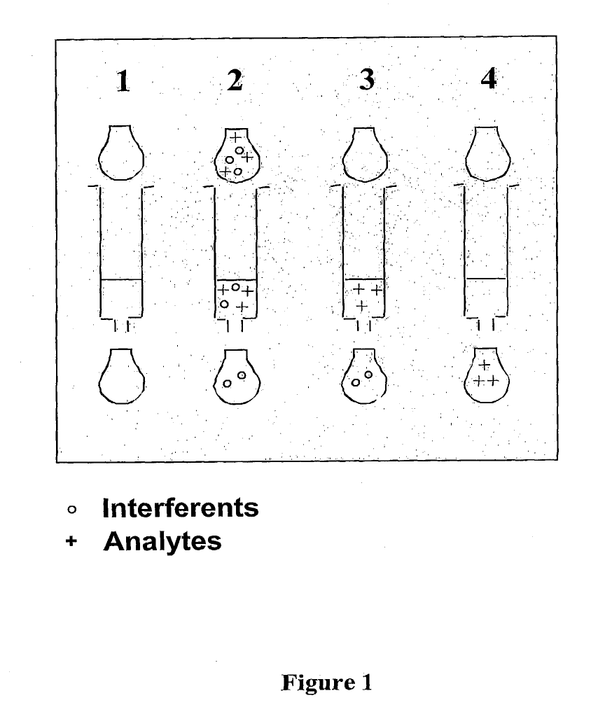

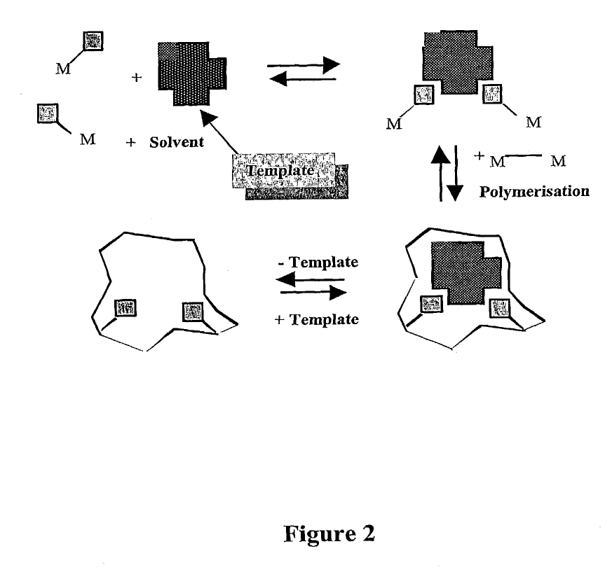

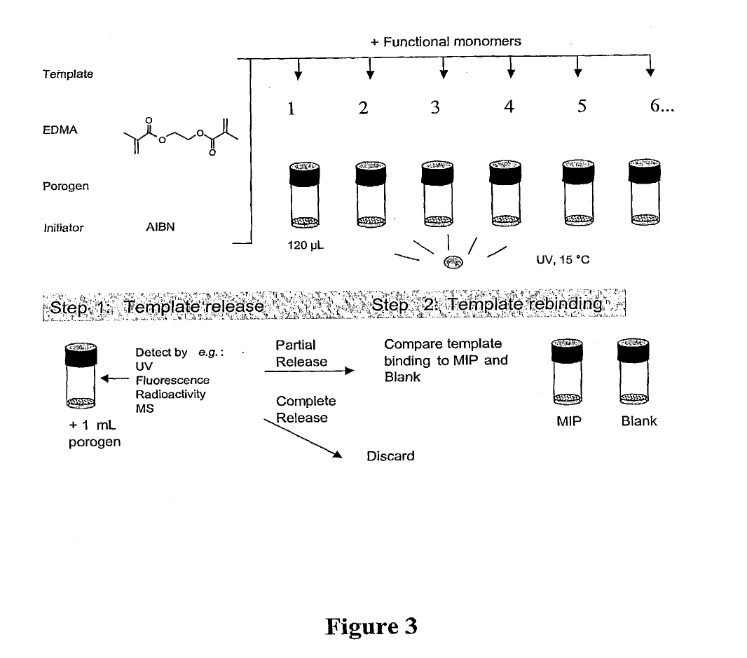

### DETAILED DESCRIPTION OF PREFERRED EMBODIMENTS

1. Combinatorial grafting of MIPs on particles with defined pore and particle sizes and subsequent packing of SPE wells.

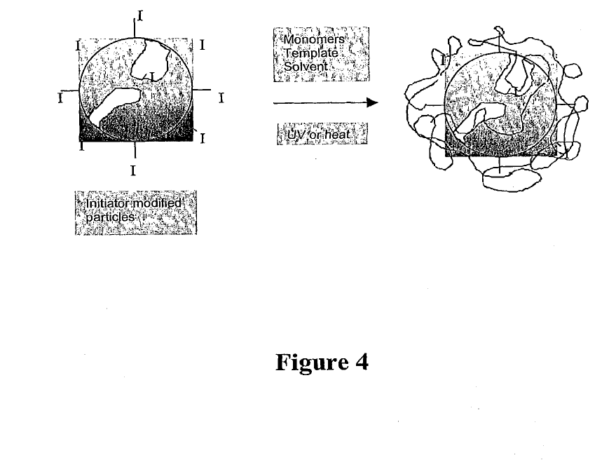

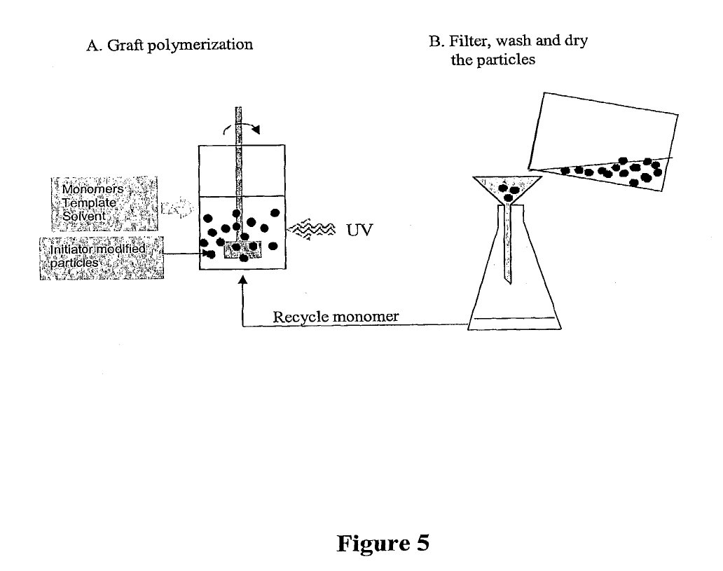

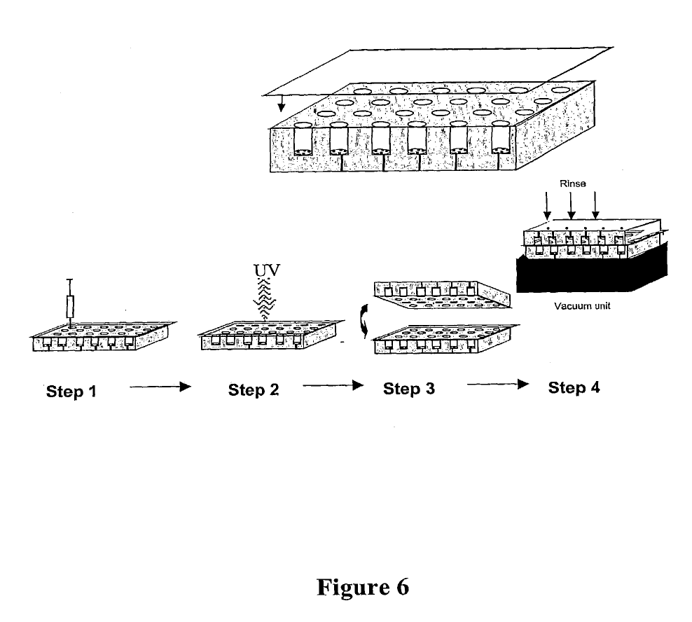

WO 01/19886 describes synthesis of MIPs on initiator modified particles and the resulting composite MIPs forms the basis of the invention. Thus imprinted polymer can be prepared by confining the chain growth to the surface of the particles (FIG. 4). This implies that a robust and continuous method for MIP production can be set up (FIG. 5). Alternatively, since chain growth in solution can be neglected, the grafting can be performed in situ in SPE well or on planar substrates. In this invention the particles will be packed in specially designed microtiter plates. The first of these are solvent resistant microtiter plates with frits with a sealable outlet (Alt 1). The other is a solvent resistant plate where the particles after grafting can be transferred to standard SPE plates (Alt 2, FIG. 6). The solvent resistant plate as shown in FIG. 6 is preferably a microtiter plate of Teflon® coated aluminium. Each well of the microtiter plate contains initiator modified particles. The amount of initiator modified particles in each well is preferably about 10-20 mg. The bottom of each well is provided with a one-way capillary for subsequent transfer of the MIP particles as described below. The top of the microtiter plate is provided with a glass lid for UV polymerisation. After filling about 10-20 mg particles in each well different monomer mixtures containing the template molecule are added in Step 1 (FIG. 6) to each well just enough to wet the particles. After polymerisation in Step 2 by UV or heat, the MIP grafted particles are transferred into standard microtiter plate extraction units in Steps 3 and 4 by stacking and inverting. In Step 3 a standard microtiter plate is stacked tightly upside down on top of the MIP containing microtiter plate obtained in Step 2. In Step 4 the stacked microtiter plates of Step 3 are inverted and the MIP particles are transferred from the solvent resistant microtiter plate to the standard microtiter plate. Efficient transfer is assured by rinsing and vacuum application. The resulting plates are then ready for use. This invention can thus be used for convenient combinatorial MIP synthesis and evaluation. As an alternative to the use of initiator modified particles, initiator modified frits or monoliths may also be used.

2. Combinatorial synthesis of MIPs as stripes for TLC evaluation of recognition properties.

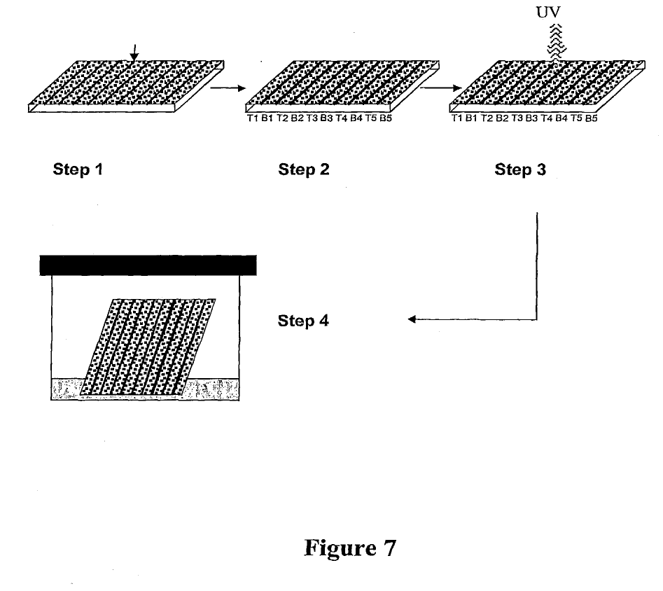

This embodiment of the invention is illustrated in FIG. 7. In Step 1 initiator modified particles are used to coat a glass plate according to standard methods for TLC-plate fabrication. After coating lanes or stripes are separated by cut crevices (solid black lines in FIG. 7), which are used to prevent mixing of neighbouring monomer mixtures. In step 2 different monomer mixtures containing template giving MIPs (T1 to T5) and in absence of template giving blanks (B1 to B5) are then added to each lane, and in Step 5 polymerisation is started by UV or heat after coating the surface with a glass plate. After polymerisation template and excess monomer are removed by washing. The recognition properties can then be directly assessed (Step 4) in a flow through mode by TLC of the template and analogues. Development of the plates is done using the standard methods for TLC development. Thus by impregnating the plate with a fluorescent label, fluorescent detection is possible. Otherwise various group specific reagents can be used. This is expected to yield a high throughput alternative to MIP development for SPE or chromatography.

3. Detection of bound-nonbound substrate or analyte based on fluorescence-, UV-, IR-, Raman- or radioactivity measurements.

After synthesis of the MIPs, rapid methods for estimating release and rebinding of template are needed. Until now this have been measured using time consuming HPLC or FIA quantification in a serial mode. Paralell methods for quantification are highly desirable. For this purpose it is possible to apply sensitive techniques to measure what is bound to the polymer in situ. However, such techniques are expected to be limited due to the complex composition of MIPs particularly since monomers and templates vary considerably in adsorption characteristics. Of more general utility would be methods relying on quantification of nonbound substrate. Thus after having separated supernatant from polymer, by pipetting or filtering, the unbound fraction can be measured by a variety of techniques depending on the nature of the template. Thus amines will be labelled with fluorescent reagents such as orthophtalaldehyde (OPA), acids can be esterified with a fluorescent or UV absorbing reagent and if radioactive labelling is available scintillation counting is possible. Thus having access to these techniques in combination with Microtiter plate Readers (Fluorescence-, UV/Vis-, Scintiallation-reading) a fast high throughput technique for MIP synthesis is possible.

### REFERENCES

1. Bartsch, R. A. & Maeda, M. in ACS Symposium Series 703 (Oxford University Press, Washington, 1998).

2. Wulff, G. Angew. Chem., Int. Ed. Engl. 34, 1812-32 (1995).

3. Sellergren, B. Trends Anal. Chem. 16, 310-320 (1997).

4. Sellergren, B. Anal. Chem. 66, 1578 (1994).

5. Andersson, L. I., Paprica, A. & Arvidsson, T. Chromatographia 46, 57-62 (1997).

6. Turkewitsch, P., Wandelt, B., Darling, G. D. & Powell, W. S. Anal. Chem. 70, 2025-2030 (1998).

7. Joshi, V. P., Karode, S. K., Kulkarni, M. G. & Mashelkar, R. A. Chem. Engn. Sci. 53, 2271-2284 (1998).

8. Sajonz, P., Kele, M., Zhong, G., Sellergren, B. & Guiochon, G. J. Chromatogr. 810, 1-17 (1998).

9. Armstrong, D. W., Schneiderheinze, J. M., Hwang, Y. -S. & Sellergren, B. Anal. Chem. 70, 3304-3314 (1998).

10. Davis, M. E., Katz, A. & Ahmad, W. R. Chem. Mater. 8, 1820-1839 (1996).

11. Sellergren, B., Wieschemeyer, J., Boos, K. -S. & Seidel, D. Chem. Mat. 10, 4037-4046 (1998).

12. Lanza, F. & Sellergren, B. Anal. Chem. 71, 2092-2096 (1999).

1. A screening method for simultaneous preparation of different molecularly imprinted polymers and flow through mode assessment of the recognition of at least one target molecule,
characterized by
a) providing particles, frits or monoliths having initiator confined to the surface thereof in separate compartments;
b) adding different monomer mixtures that may contain a template molecule to each compartment;
c) polymerising said mixtures;
d) removing the template and excess monomer(s) from the compartments;
e) adding said target molecule(s) to the compartments; and
f) evaluating the recognition of said target molecule(s) by the molecularly imprinted polymers in the compartments, in flow through mode.

2. A method according to claim 1, wherein said compartments are wells of a microtiter plate.

3. A method according to claim 2, wherein said compartments are wells of a microtiter plate for flow-through solid phase extraction.

4. A method according to claim 1, wherein said compartments are lanes of a TLC-plate.

5. A screening device for the application of a method according to any of claims 1-4 containing different molecularly imprinted polymers for flow through mode assessment of the recognition of at least one target molecule,
characterized in that it is obtainable by
a) providing particles, frits or monoliths having initiator confined to the surface thereof in separate compartments;
b) adding different monomer mixtures that may contain a template molecule to each compartment;
c) polymerising said mixtures;
d) removing the template and excess monomer(s) from the compartments;
e) adding said target molecule(s) to the compartments; and
f) evaluating the recognition of said target molecule(s) by the molecularly imprinted polymers in the compartments, in flow through mode.

6. A device according to claim 5, wherein said compartments are wells of a microtiter plate.

7. A device according to claim 6, wherein said compartments are wells of a microtiter plate for flow-through solid phase extraction.

8. A device according to claim 5, wherein said compartments are lanes of a TLC-plate.

9. Use of a device according to any one of claims 5-8, for assessment of the recognition properties of said molecularly imprinted polymers.

10. Use of a device according to any one of claims 5-8, in solid phase extraction.
